(19) United States
(12) Patent Application Publication
(10) Pub. No.: US 2023/0242709 A1
(43) Pub. Date: Aug. 3, 2023

(54) THERMOSET COMPOSITE COMPRISING A CROSSLINKED IMIDE EXTENDED COMPOUND

(71) Applicant: Rogers Corporation, Chandler, AZ (US)

(72) Inventors: Thomas A. Koes, Riverside, CA (US); Nazeef Azam, Ellington, CT (US); Murali Sethumadhavan, Richmond (GB)

(21) Appl. No.: 18/093,381

(22) Filed: Jan. 5, 2023

Related U.S. Application Data
(60) Provisional application No. 63/300,676, filed on Jan. 19, 2022.

(51) Int. Cl. C08G 73/12; C08K 5/3492; C08K 3/36; C08K 9/04

(52) U.S. Cl. CPC C08G 73/12; C08K 3/36; C08K 5/34924; C08K 9/04; C08K 2201/003

(57) ABSTRACT

In an aspect, a thermosettable composition comprises an imide extended compound and a reactive monomer that is free-radically crosslinkable with the reactive end groups of the imide extended compound to produce a crosslinked network. A thermoset composite can be derived from the thermosettable composition and a multilayer article can include the thermoset composite in the form of a layer. The article can be an antenna, a bond ply, a semiconductor substrate build-up/redistribution layer dielectric film, a circuit board, resin-coated-copper (RCC), or a flexible core.

### CROSS REFERENCE TO RELATED APPLICATION

This application claims the benefit of U.S. Provisional Pat. Application Serial No. 63/300,676 filed Jan. 19, 2022, which is incorporated herein in its entirety by reference.

### BACKGROUND

High performance materials can benefit from having a low loss, a low lamination temperature, and good flowability among other desirable properties. For example, desirable attributes for a circuit bond-ply or build-up thin film having low thicknesses with acceptable handling characteristics, being tack free, having low-to-no-odor, having a reasonable shelf-life at room temperature, having a reduced lamination temperature, being amenable to traditional circuit fabrication processing including semi-additive processing, having sufficient resin fill-and-flow using reasonable lamination pressures and temperature ramp rates, having a low z-axis coefficient of thermal expansion, and/or having good peel strength to copper. Developing such materials is difficult as changing a formulation to improve one property is often disadvantageous for other properties.

In view of the above, there remains a need for improved high performance dielectric composites with a tunable range of properties. Specifically, there is a need for materials having an improved combination of properties, including a high peel strength to metal foils, and low dissipation loss, among other desired electrical, thermal, and physical properties.

### BRIEF SUMMARY

Disclosed herein is a thermoset composite, method of making, and articles derived therefrom.

In an aspect, a thermosettable composition comprises an imide extended compound of the following structure:

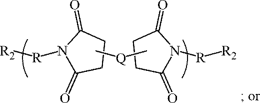

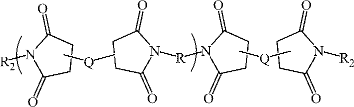

wherein R and Q are each independently divalent substituted or unsubstituted aliphatic, alkenyl, aromatic, heteroaromatic groups, or a divalent siloxane group; and each R₂ independently comprises a reactive alkenyl end group; and a reactive monomer that is free-radically crosslinkable with the reactive end groups of the imide extended compound to produce a crosslinked network.

The above described and other features are exemplified by the following figures, detailed description, and claims.

### BRIEF DESCRIPTION OF THE DRAWINGS

The figures are illustrative of the examples, which are not intended to limit devices made in accordance with the disclosure to the materials, conditions, or process parameters set forth herein.

FIG. 1 is a photographic image of an imide extended composite of Example 1 lying flat on a table;

FIG. 2 is a photographic image of a PPO composite of Example 2 that is bent; and

FIG. 3 is a photographic image of three glass substrates of Example 3.

### DETAILED DESCRIPTION

A composite was developed that is derived from a thermosettable composition comprising an imide extended compound and a reactive monomer. The composite can exhibit an excellent balance of properties and can be altered to be used in various applications including be a prepreg, a resin-coated electrically conductive (RCC) layer, a circuit board, a bond ply, a cover film, a build-up material, a build-up film, or a flexible core.

The imide extended compound can comprise a compound having a structure of at least one of Formula (1) or Formula (2),

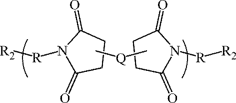

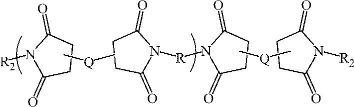

wherein each R independently is a divalent substituted or unsubstituted aliphatic, alkenyl, aromatic, or heteroaromatic group, or is a divalent siloxane group; each Q independently is a divalent or tetravalent substituted or unsubstituted aliphatic, alkenyl, aromatic, or heteroaromatic group, or a divalent siloxane group, and each R₂ independently comprises a reactive alkenyl endgroup.

R can be linear, branched, or cyclic. R can be a hydrocarbon group. R can include 1 to 100 carbon atoms, or 10 to 90 carbon atoms, or 20 to 40 carbon atoms. R can be a branched, alkylene group or a branched, aliphatic group, for example, having 20 to 40 carbon atoms. R can be a C₁₋₅₀, or a C₃₀₋₄₀ divalent hydrocarbon group. R can be a substituted or unsubstituted C₁₋₅₀, or a C₃₀₋₄₀ divalent alkane optionally including one or more cyclic alkane moieties and optionally containing 0 to 3 unsaturations. When R includes a branched, alkylene group or a branched, aliphatic group the flexibility of the composite can be improved.

Q can be a hydrocarbon group having 1 to 100 carbon atoms, 2 to 50 carbon atoms, or 4 to 10 carbon atoms. Q can be a substituted or unsubstituted siloxane group, for example, that is derived from dimethyl siloxane, methylphenyl siloxane, or diphenyl siloxane. Q can be substituted, for example, with at least one of an acyl group, an alkyl group, an alkenyl group, an alkoxy group, an alkynyl group, an amide group, an amino group, an aryl group, an aryloxy group, a carbamate group, a carboxyl group, a cyano group, a cycloalkyl group, a haloalkyl group, a halogen atom, a heterocyclic group, a heteroaryl group, a hydroxyl group, a mercapto group, a nitro group, a nitroso group, —C(O)H, —NRₓC(O)— N(Rₓ)₂, —OC(O)—N(Rₓ)₂, an oxyacyl group, or a sulfonamide group, where Rₓ can be a hydrogen atom of an alkyl group. Q can be a substituted or unsubstituted tetravalent organic group having 1 to 100 carbon atoms, or 2 to 50 carbon atoms, or 4 to 10 carbon atoms.

Q can be a tetravalent aryl group, for example, to result in a repeating group having the Formula Q1. Q1 can result in a composite with increased mechanical strength relative to non-aromatic groups. Q1 can be derived from pyromellitic anhydride. Q can be a tetravalent aryloxy group, for example, to result in a repeating group having the Formula Q2. Q2 can be derived from 4,4′-oxydiphthalic anhydride.

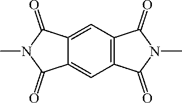

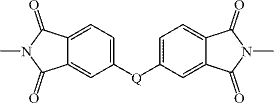

R₂ can be a maleimide group, a citraconimide group, a styryl group, a vinylbenzyl group, a vinyl group, an allyl group, an alkynyl group, a propargyl ether group, a cyano group, a vinyl ether group, a vinyl ester group, an acrylate group, a methacrylate group, an oxazoline group, a benzoxazine group, or a methyl norbornene group.

The imide extended compound can comprise a bis-maleimide compound of the Formula (3).

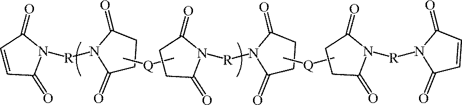

The imide extended compound can comprise a bis-styryl compound of the Formula (4).

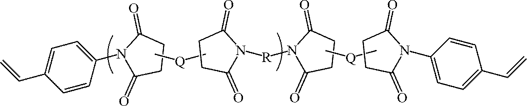

The imide extended compound can comprise a bis-vinylbenzyl compound of the Formula (5).

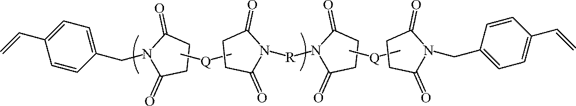

The imide extended compound can comprise a bis-vinyl compound of the Formula (6).

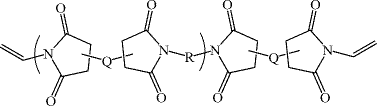

The imide extended compound can comprise a bis-allyl compound of the Formula (7).

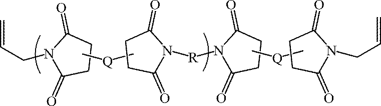

The imide extended compound can comprise a compound having the Formula (8).

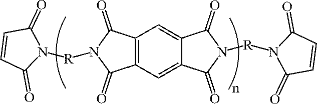

The imide extended compound can have a degree of polymerization (for example, as illustrated as n in formula 8) of 1 to 100, or 2 to 10.

The thermosettable composition can comprise 10 to 90 volume percent (vol%), or 25 to 75 vol%, or 30 to 50 vol% of the imide extended compound based on the total volume of the composition.

The thermosettable composition comprises a reactive monomer that is free-radically crosslinkable with the reactive end groups of the imide extended compound to produce a crosslinked network. The reactive monomer can comprise a triallyl (iso)cyanurate. The triallyl (iso)cyanurate comprises at least one of triallyl isocyanurate and triallyl cyanurate as illustrated in Formula (A) and Formula (B), respectively.

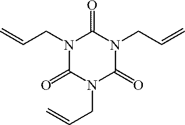 [SMILES: C=CCn1c(=O)n(CC=C)c(=O)n(CC=C)c1=O]

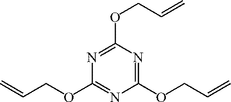 [SMILES: C=CCOc1nc(OCC=C)nc(OCC=C)n1]

The composition can comprise 1 to 40 vol%, or 10 to 35 vol%, or 20 to 30 vol% of the reactive monomer based on the total volume of the composition.

Other copolymerizable monomers include, but are not limited to, vinylaromatic monomers, for example substituted and unsubstituted monovinylaromatic monomers such as styrene, 3-methylstyrene, 3,5-diethylstyrene, 4-n-propylstyrene, alpha-methylstyrene, alpha-methylvinyltoluene, para-hydroxystyrene, 4-acetoxystyrene, para-methoxystyrene, alpha-chlorostyrene, alpha-bromostyrene, dichlorostyrene, dibromostyrene, tetra-chlorostyrene and the like; and substituted and unsubstituted divinylaromatic monomers such as divinylbenzene, divinyltoluene and the like. Combinations comprising at least one of the foregoing copolymerizable monomers can also be used.

Still other optional crosslinkers are trimethylolpropane trimethacrylate (TMP TMA), pentaerythritol tetraacrylate (PETA) or isocyanuric acid tris(2-acryloyloxy ethyl) ester (THEIC triacrylate), diallyl phthalate and other multifunctional (meth)acrylate monomers (e.g., the SARTOMER resins available from Sartomer USA, Exton, PA) and a combination comprising at least one of the foregoing, all of which are commercially available.

The thermosettable composition can comprise a free-radical initiator that can thermally decompose to form free radicals, which then initiate polymerization of ethylenically unsaturated double bonds within the composition. These initiators generally provide weak bonds, for example, bonds that have small dissociation energy. The free-radical initiator can comprise at least one of a peroxide initiator, an azo initiator, a carbon-carbon initiator, a persulfate initiator, a hydrazine initiator, a hydrazide initiator, a benzophenone initiator, or a halogen initiator. The free-radical initiator can comprise 2,3-dimethyl-2,3-diphenylbutane, 3,4-dimethyl-3,4-diphenylhexane, or poly(1,4-diisopropylbenzene). The initiator can comprise an organic peroxide, for example, at least one of dicumyl peroxide, t-butylperbenzoate, α, α′-di-(t-butyl peroxy) diisopropylbenzene, or 2,5-dimethyl-2,5-di(t-butylperoxy)-3-hexyne. The initiator can be light sensitive comprising, for example, α-hydroxy ketone, phenylglyoxylate, benzyldimethyl-ketal, α-amino ketone, monoacyl phosphine (MAPO), bisacyl phosphine (BAPO), diphenyl(2,4,6-trimethylbenzoyl) phosphine oxide (TPO), phosphine oxides or metallocenes.

The free-radical initiator can comprise at least one of methyl ethyl ketone peroxide, cyclohexanone peroxide, 1,1-bis(t-butyl peroxy)-3,3,5-trimethylcyclohexane, 2,2-bis(t-butyl peroxy)butane), t-butyl hydroperoxide, 2,5-dimethylhexane-2,5-dihydroperoxide, or 2,5-dimethyl-2,5-di(benzoylperoxy)hexane, octanoyl peroxide, isobutyryl peroxide, dibenzoyl peroxide, peroxydicarbonate, α,α′-azobis(isobutyronitrile), a redox initiator, or acetyl azide.

The free-radical initiator can be present in an amount of 0.1 to 5 weight percent (wt%), or 0.1 to 1.5 wt% based on the total weight of the thermosetting composition. The free-radical initiator can be present in an amount of 0 to 10 vol%, or 2 to 8 vol%, or 0.1 to 3 vol% based on the total volume of the composition.

The thermosettable composition can comprise a fused silica. All or a portion of the fused silica can be capable of chemically coupling to the crosslinked network. The fused silica can comprise a surface treatment, for example, to hydrophobize the fused silica. The surface treatment can be formed by grafting a silane onto the fused silica. The silane can comprise a reactive end group capable of chemically coupling to the crosslinked network.

The silane can comprise at least one of a phenyl silane or a fluorosilane. The phenyl silane can comprise at least one of p-chloromethyl phenyl trimethoxy silane, phenyl trimethoxy silane, phenyl triethoxy silane, phenyl trichlorosilane, phenyl-tris-(4-biphenylyl)silane, (phenoxy) triphenyl silane, or a functionalized phenyl silane. The functionalized phenyl silane can have the formula R′SiZ¹R²Z² wherein R′ is alkyl with 1 to 3 carbon atoms, —SH, —CN, —N₃ or hydrogen; Z¹ and Z² are each independently chlorine, fluorine, bromine, alkoxy with not more than 6 carbon atoms, NH, —NH₂, -NR2’; and R² is

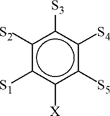

wherein each of the S-substituents, S₁, S₂, S₃, S₄ and S₅ are independently hydrogen, alkyl with 1 to 4 carbon atoms, methoxy, ethoxy, or cyano, provided that at least one of the S-substituents is other than hydrogen, and when there is a methyl or methoxy S-substituent, then (i) at least two of the S-substituents are other than hydrogen, (ii) two adjacent S-substituents form with the phenyl nucleus a naphthalene or anthracene group, or (iii) three adjacent S-substituents form together with the phenyl nucleus a pyrene group, and X is the group —(CH₂)ₙ—, wherein n is 0 to 20, or 10 to 16 when n is not 0, in other words, X is an optional spacer group. The term “lower” in connection with groups or compounds, means 1 to 7 and, or 1 to 4 carbon atoms.

The fluorosilane can be beneficial as compared to other silanes as the fluorine atom has the lowest polarizability of all the atoms and fluorinated molecules therefore exhibit very weak intermolecular dispersion forces. As a result, fluorinated molecules are remarkably, both hydrophobic and oleophobic at the same time. In order to take full advantage of the hydrophobizing potential of fluorinated compounds in the composite, the fused silica can be pre-treated with a fluorinated silane prior to forming the composite instead of performing an in-situ silanization of the fused silica in a composite. Pre-treating the fused silica can be preferential due to the oleophobicity (immiscibility) of the fluorinated silane in the composite. It is noted that just as it can be beneficial to pre-treat the fused silica with a fluorinated silane prior to forming the composite, it can likewise be beneficial to pre-treat the fused silica with other hydrophobic silanes.

The fluorosilane coating can be formed from a perfluorinated alkyl silane having the formula: CF₃(CF₂)ₙ—CH₂CH₂SiX, wherein X is a hydrolyzable functional group and n=0 or a whole integer. The fluorosilane can comprise at least one of (3,3,3-trifluoropropyl)trichlorosilane, (3,3,3-trifluoropropyl)dimethylchlorosilane, (3,3,3-trifluoropropyl)methyldichlorosilane, (3,3,3-trifluoropropyl)methyldimethoxysilane, (tridecafluoro-1,1,2,2-tetrahydrooctyl)-1-trichlorosilane, (tridecafluoro-1,1,2,2-tetrahydrooctyl)-1-methyldichlorosilane, (tridecafluoro-1,1,2,2-tetrahydrooctyl)-1-dimethylchlorosilane, (heptadecafluoro-1,1,2,2-tetrahydrodecyl)-1-methyldichlorosilane, (heptadecafluoro-1,1,2,2-tetrahydrodecyl)-1-trichlorosilane, heptadecafluoro-1,1,2,2-tetrahydrodecyl)-1-dimethylchlorosilane, (heptafluoroisopropoxy) propylmethyl dichlorosilane, 3-(heptafluoroisopropoxy) propyltrichlorosilane, 3-(heptafluoroisopropoxy), or propyltriethoxysilane. The fluorosilane can comprise perfluorooctyltriethoxysilane.

The silane can comprise at least one of an aminosilane or a silane containing a polymerizable functional group such as an acryl or a methacryl group. Examples of aminosilanes include at least one of N-methyl-γ-aminopropyltriethoxysilane, N-ethyl-γ-aminopropyltrimethoxysilane, N-methyl-β-aminoethyltrimethoxysilane, N-methyl-γ-aminopropylmethyldimethoxysilane, γ-aminopropylmethyldimethoxysilane, N-(β-N-methylaminoethyl)-γ-aminopropyl triethoxysilane, aminoethylamino propyl trimethoxy silane, N-(γ-aminopropyl)-γ-aminopropylmethyldimethoxysilane, (2-ethylpiperidino) (5-hexenyl)methylchlorosilane, 2-ethylpiperidinodimethylhydridosilane, 2-ethylpiperidinotrimethylsilane, 2-ethylpiperidinomethylphenylchlorosilane, 2-ethylpiperidinodicyclopentylchlorosilane, morpholinovinylmethylchlorosilane, N-(y-aminopropyl)-N-methyl-γ-aminopropylmethyldimethoxysilane and γ-aminopropylethyldiethoxysilaneaminoethylamino trimethoxy silane, or n-methylpiperazinophenyldichlorosilane.

The fused silica can be functionalized with functional groups comprising at least one of a (meth)acrylate group, a vinyl group, an allyl group, a propargyl group, a butenyl group, a styryl group, or a vinyl benzyl group; preferably wherein a functional group of the functionalized fused silica comprises a (meth)acrylate group. Silanes including a polymerizable functional group include silanes of the formula R^{a}ₓSiR^{b}₍₃₋ₓ₎R, in which each R^{a} is the same or different (for example, the same) and is halogen (for example, Cl or Br), C₁₋₄ alkoxy (for example, methoxy or ethoxy), or C₂₋₆ acyl; each R^{b} is a C₁₋₈ alkyl or C₆₋₁₂ aryl (for example, R^{b} can be methyl, ethyl, propyl, butyl or phenyl); x is 1, 2 or 3 (for example, 2 or 3); and R is -(CH₂)ₙOC(=O)C(R^{c})=CH₂, wherein R^{c} is hydrogen or methyl and n is an integer 1 to 6, or, 2 to 4. The silane can comprise at least one of methacrylsilane(3-methacryloxypropyl trimethoxy silane) or trimethooxyphenylsilane.

The fused silica can have a spherical morphology having a median diameter of 1 to 50 micrometers, 1 to 10 micrometers, or less than 1 micrometer. The fused silica can have a D90 particle size of 1 to 20 micrometers, or 5 to 15 micrometers. As used herein, the particle size can be determined using dynamic light scattering.

The composition can comprise 10 to 70 vol%, or 20 to 60 vol%, or 30 to 55 vol% of the fused silica based on the total volume of the composition. The composition can comprise 10 to 70 vol%, or 20 to 60 vol%, or 30 to 55 vol% of the functionalized fused silica based on the total volume of the composition.

The thermosettable composition can comprise a ceramic filler other than or in addition to the fused silica. The ceramic filler can comprise at least one of fumed silica, a silane treated fumed silica, titanium dioxide, barium titanate, strontium titanate, corundum, wollastonite, Ba₂Ti₉O₂₀, hollow ceramic spheres, boron nitride, aluminum nitride, silicon carbide, beryllia, alumina, alumina trihydrate, magnesia, mica, talc, nanoclay, or magnesium hydroxide. The surface of ceramic filler can also be modified using physical vapor deposition (PVD) and/or chemical vapor deposition (CVD) such as, but not limited to atomic layer deposition (ALD). The ceramic filler can be present in an amount of 10 to 70 vol%, or 20 to 60 vol%, or 30 to 55 vol% of the fused silica based on the total volume of the composition. The composition can comprise 10 to 70 vol%, or 20 to 60 vol%, or 30 to 55 vol% of the functionalized fused silica based on the total volume of the composition.

The thermosettable composition can comprise 10 to 90 vol% of the imide extended bismaleimide of the Formula 8, 1 to 40 vol% of a triallyl (iso)cyanurate; 0.1 to 10 vol% of the free-radical initiator; and 10 to 70 vol% of a methacrylate functionalized fused silica; wherein the volumes are based on the total volume of the thermosettable composition. Likewise, a thermoset composite can comprise 10 to 90 vol% of the imide extended bismaleimide of the Formula 8, 1 to 40 vol% of a triallyl (iso)cyanurate; 0.1 to 10 vol% of the free-radical initiator; and 10 to 70 vol% of a methacrylate functionalized fused silica; wherein the volumes are based on the total volume of the composite.

The thermosettable composition can comprise a flame retardant. The flame retardant can comprise at least one of a metal hydrate, an organic flame retardant, an organometallic flame retardant or a halogenated flame retardant.

The metal hydrate can comprise a hydrate of a metal, for example, at least one of Mg, Ca, Al, Fe, Zn, Ba, Cu, or Ni. Hydrates of Mg, Al, or Ca can be used, for example, at least one of aluminum hydroxide, magnesium hydroxide, calcium hydroxide, iron hydroxide, zinc hydroxide, copper hydroxide, nickel hydroxide, or hydrates of calcium aluminate, gypsum dihydrate, zinc borate, zinc stannate, or barium metaborate. Composites of these hydrates can be used, for example, a hydrate containing Mg and at least one of Ca, Al, Fe, Zn, Ba, Cu, or Ni. A composite metal hydrate can have the formula MgMₓ(OH)_{y} wherein M is Ca, Al, Fe, Zn, Ba, Cu, or Ni, x is 0.1 to 10, and y is 2 to 32. The metal hydrate can have a volume average particle diameter of 1 to 500 nanometers (nm), or 1 to 200 nm, or 5 to 200 nm, or 10 to 200 nm; alternatively the volume average particle diameter can be 500 nm to 15 micrometers, for example, 1 to 5 micrometers.

The organic flame retardant can comprise at least one of melamine cyanurate, phosphorus-containing compounds (for example, melamine polyphosphate, an aliphatic or aromatic phosphinate, a diphosphinate, a phosphonate, a phosphazene, a phosphite, a phosphene, or a phosphate), a polysilsesquioxane, or a siloxane. Either the organic or organometallic flame retardant can be halogen-free.

The halogenated flame retardant can comprise at least one of hexachloroendomethylenetetrahydrophthalic acid (HET acid), tetrabromophthalic acid, dibromoneopentyl glycol, bis-pentabromophenyl ethane (commercially available as SAYTEX 8010), ethylene bistetrabromophthalimide (commercially available as SAYTEX BT93W), tetradecabromodiphenoxy benzene (commercially available as SAYTEX 120), or decabromodiphenyl oxide (commercially available as SAYTEX 102).

The flame retardant can be used in combination with a synergist, for example, a halogenated flame retardant can be used in combination with a synergists such as antimony trioxide, and a phosphorus-containing flame retardant can be used in combination with a nitrogen-containing compound such as melamine.

The flame retardant particles can be coated or otherwise treated to improve dispersion and other properties. The flame retardant can be present in an amount of 5 to 25 vol%, or 8 to 20 vol% on the total volume of the composition. The composition can be free of a flame retardant, for example, comprising 0 to 0.5 vol%, or 0 vol% of the flame retardant based on the total volume of the composition.

The thermosettable composition can comprise a solvent. The solvent can be selected so as to dissolve the thermosetting components, disperse particulate additives and any other optional additives that can be present, and to have a convenient evaporation rate for forming, drying, and b-staging. The solvent can comprise at least one of xylene, toluene, methyl ethyl ketone (MEK), methyl isobutyl ketone (MIBK), hexane, a higher liquid linear alkane (for example, heptane, octane, or nonane), cyclohexane, cyclohexanone, isophorone, glycol ether PM, glycol ether PM acetate, ethyl lactate, or a terpene-based solvent. The solvent can comprise at least one of xylene, toluene, methyl ethyl ketone, methyl isobutyl ketone or hexane. The solvent can comprise at least one of xylene or toluene. The solvent can be present in an amount of 2 to 80 wt%, or 40 to 60 wt%, or 2 to 5 wt% based on the total weight of the thermosetting composition including the solvent. The thermosetting composition can comprise 20 to 98 wt% solids (all components other than the solvent), or 40 to 60 wt%, or 95 to 98 wt% solids, based on the total weight of the thermosetting composition including the solvent. The resultant composite can be free of the solvent, for example, comprising only a residual amount after curing. The composite can comprise 0 to 0.5 wt%, or 0 to 0.05 wt%, or 0 wt% of the solvent based on the total weight of the composite including the solvent.

A composite formed from the thermosettable composition can comprise a reinforcing fabric (also referred to as a fabric or a reinforcing layer). The fabric can comprise a fibrous layer comprising a plurality of thermally stable fibers. The fabric can be woven or non-woven, such as a felt. The fabric can reduce shrinkage of the composite upon cure within the plane of the composite. In addition, the use of the fabric can help render the composite with a relatively high dimensional stability and mechanical strength (modulus). Such materials can be more readily processed by methods in commercial use, for example, lamination, including roll-to-roll lamination.

The fabric can comprise thermally stable fibers. The thermally stable fibers can comprise glass fibers such as at least one of E glass fibers, S glass fibers, D glass fibers, or lower dielectric constant, lower dissipation loss fibers such as NE glass fibers, L glass fibers, or quartz fibers. For example, lower dielectric constant, lower dissipation factor, thermally stable fibers such as NITTOBO NE commercially available from Nitto Boseki Co., Ltd. of Tokyo, Japan or L glass fiber commercially available from AGY, Aiken, South Carolina or Shin-Etsu SQX commercially available from Shin-Etsu Chemical Co., Ltd. of Tokyo, Japan. The thermally stable fibers can comprise polymer-based fibers such as high temperature polymer fibers, pulp or fibrillated pulp. The polymer-based fibers can comprise a liquid crystal polymer such as VECTRAN commercially available from Kuraray America Inc., Fort Mill, SC. The polymer-based fibers can comprise at least one of polyetherimide (PEI), polyether ketone (PEK), polyether ether ketone (PEEK), polysulfone (PSU), polyethersulfones (PES or PESU), polyphenylene sulfide (PPS), polycarbonate (PC), poly m-aramid (fibers or fibrids), poly p-aramid, polyvinylidene difluoride (PVDF) or polyester (such as PET). The polymer-based fibers can comprise at least one of liquid crystalline polymer (LCP) fibers, aramid fibers, cyclic-olefin-copolymer (COC) fibers or ultrahigh molecular weight polyethylene (UHMWPE) fibers.

Thermally stable fabrics comprising glass fibers can be plain weave or spread-weave and can be balanced. Spread-weaves can reduce signal skew and crosstalk, enhance impedance control, resistance to conductive anodic filament (CAF) growth, dimensional stability, prepreg yields and can be more amenable to laser drilling during circuit fabrication. The fabric can comprise a lower dielectric constant, lower dissipation factor spread-weave fabric.

The thermosettable composition can be coated on one or both sides of the fabric and/or can penetrate the reinforcing layer such that it is integral to the composite layer formed during curing. The fabric can have a thickness of 5 to 100 micrometers, or 10 to 60 micrometers. The fabric can be present in an amount of 5 to 40 wt%, or 15 to 25 wt% based on the total weight of the composite.

The composite can have a peel strength to copper of greater than or equal to 0.35 kilograms per centimeter as determined in accordance with “Peel Strength of Metallic Clad Laminates” (IPC-TM-650 2.4.8).

The composite can have an average coefficient of thermal expansion in the z-direction of less than or equal to 40 parts per million per degree Celsius (ppm/°C), or less than or equal to 35 ppm/°C, or 25 to 90 ppm/°C, or 60 to 85 ppm/°C from -50 to 150° C. determined in accordance with the “Glass Transition Temperature and Thermal Expansion of Materials Used in High Density Interconnection (HDI) and Microvias - TMA Method” (IPC-TM-650 2.4.24.5).

The composite can have a permittivity of 2.5 to 3.5 measured in accordance with the “Split Post Dielectric Resonator (SPDR) Technique for Precise Measurements of Laminar Dielectric Specimens” (IEEE Xplore Conference Paper, February 2000) at a temperature of 23 to 25° C., 50% relative humidity and at a frequency of 10 gigahertz (GHz).

The composite can have a dielectric loss of less than or equal to 0.0025, or less than or equal to 0.0020, or 0.001 to 0.0025 measured in accordance with the “Split Post Dielectric Resonator (SPDR) Technique for Precise Measurements of Laminar Dielectric Specimens” (IEEE Xplore Conference Paper, February 2000) at a temperature of 23 to 25° C., 50% relative humidity and at a frequency of 10 gigahertz (GHz).

The composite can have a UL94 V0 rating at a thickness of 84 to 760 micrometers determined in accordance with the Underwriter’s Laboratory UL 94 Standard For Safety “Tests for Flammability of Plastic Materials for Parts in Devices and Appliances.”

The composite can have an elastic modulus of less than or equal to 4 gigapascals (GPa, or less than or equal to 2 GPa, or 0.4 to 1.5 GPa determined in accordance with “Glass Transition and Modulus of Materials Used in High Density Interconnection (HDI) and Microvias - DMA Method” (IPC-TM-650 2.4.24.4).

The composite can have a minimum melt viscosity of 100 to 3,000 Poise, or 1,000 to 3,000 poise, or 2,000 to 2,900, or 150 to 300 Poise determined using parallel plate oscillatory rheology with a ramping temperature of 10° C. per minute.

A method of making the composite can comprise curing a layer formed from the thermosettable composition. The curing can comprise at least one increasing a temperature of the layer or exposing the layer to an electron-beam irradiation or exposing the layer to ultraviolet (UV) irradiation. The method can further comprise at least one of forming the layer by casting the composition on a release liner, casting the composition on a metal foil such as copper or aluminum, or impregnating a reinforcing fabric with the composition prior to the curing.

A prepreg can be formed by treating a fabric with the thermosetting composition and partially curing (b-staging) the thermosetting composition. As used herein, the term b-staging can refer to: (1) the thermosetting composition optionally present in a solvent carrier being (2) applied to a surface, for example, a woven fiberglass, followed by (3) evaporation of the optional solvent carrier below the onset temperature for polymerization to occur followed by (4) further application of heat in order to (5) partially polymerize (or partially cure) the thermosetting composition followed by (6) cooling so as to not completely polymerize the thermosetting composition. Partially curing the thermosetting composition can be particularly useful for applications where it is important to regulate the amount of resin flow that occurs when heat and pressure are applied to the b-staged system. Subsequent to forming the b-staged system, the b-staged system can be exposed to an additional heat and the partially cured thermosetting composition can be fully cured. This final polymerization is often referred to as c-staging. Examples of forming a composite via a partially cured composite include first manufacturing a b-staged thermosetting composition (otherwise known as a prepreg) and then either laminating the prepreg in the same facility to form a c-staged laminate or laminating the prepreg in a different facility. Lamination usually comprises the application of both heat and pressure and is often performed to form multilayer structures.

The thermosetting composition can be formed by combining the various components, in any order, optionally in the melt or in an inert solvent. The combining can be by any suitable method, such as blending, mixing, or stirring. The components used to form the thermosetting composition can be combined by dissolving or suspending the component in a solvent to provide a coating mixture or solution. The forming of the prepreg can comprise holding the treated fabric at an elevated temperature for a sufficient time to volatilize the formulation solvent(s) and at least partially cure (b-stage) the thermosetting composition. After forming the prepreg, the prepreg can be stored for a period of time prior to fully curing the material during the manufacture, for example, of a circuit laminate or other circuit subassembly. In one type of construction, multilayer laminates can comprise two or more plies of the prepreg between electrically conductive layers.

The method for treating the fabric with the thermosetting composition is not limited and can be performed, for example, by dip coating or roll coating, optionally at an increased temperature. A single ply prepreg can have a thickness of 10 to 200 micrometers, or 30 to 150 micrometers. It is noted that if a single ply, unclad material is desired, then the thermosetting composition can be fully cured to form the composite.

The method for casting an unreinforced film layer, such that it is free of a reinforcing fabric, such as a build-up film or a bond-ply comprising the thermosetting composition is not limited and can be performed, for example, by slot die or knife-over-roll application techniques. The thermosetting composition can be horizontally cast onto a carrier film that is thermally robust and of appropriate tensile strength. In a roll-to-roll conveyorized process for example, the carrier film conveys the unreinforced film layer through an oven and serves as an interleaf for the unreinforced film layer upon rewind. The carrier film can also support the unreinforced film layer through subsequent sheeting, paneling, and end-use handling. The carrier film, which can also be referred to as a release liner, can exhibit a specific surface energy range ensuring a defect-free liquid film coating of the thermosetting composition, anchorage (adherence) of the resulting unreinforced film layer to the carrier film through an oven as it dries and/or is potentially b-staged and facile release of the unreinforced film layer from the carrier film just prior to end-use.

Two or more prepregs and/or two or more unreinforced film layers can be laminated together to form the composite material. A circuit material comprising the composite can likewise be formed by laminating at least one ply of the prepreg and/or one ply of the unreinforced film layer and at least one electrically conductive layer.

The laminating can entail laminating a layered structure comprising a dielectric stack of one or more prepregs and/or a layered structure comprising a dielectric stack of one or more unreinforced film layers, an electrically conductive layer, and an optional intermediate layer between the dielectric stack and the electrically conductive layer to form the laminate. Likewise, the layered structure can comprise the dielectric stack without the electrically conductive layer if so desired. The electrically conductive layer can be in direct contact with the dielectric stack, without the intermediate layer. The dielectric stack can comprise 1 to 200 plies, or 2 to 50, or 5 to 100 plies and at least one electrically conductive layer can be located on an outer most side of the dielectric stack. The layered structure can then be placed in a press, e.g., a vacuum press, under a pressure and temperature and for duration of time suitable to bond the layers, forming the laminate. Optionally, the layered structure can be roll-to-roll laminated or autoclaved.

Lamination and optional curing can be by a one-step process, for example, using a vacuum press, or can be by a multi-step process. In a one-step process, the layered structure can be placed in a press, brought to a laminating pressure and heated to a laminating temperature. The laminating temperature can be 100 to 390° C., or 100 to 250° C., or 100 to 240° C., or 100 to 175° C., or 150 to 170° C. The laminating pressure can be 1 to 3 megapascal (MPa), or 1 to 2 MPa, or 1 to 1.5 MPa. The laminating temperature and pressure can be maintained for a desired dwell (soak) time, for example, 5 to 150 minutes, or 5 to 100 minutes, 10 to 50 minutes, and thereafter cooled, optionally at a controlled cooling rate (with or without applied pressure), for example, to less than or equal to 150° C.

An electrically conductive layer can be applied by laser direct structuring. Here, the composite material can comprise a laser direct structuring additive; and the laser direct structuring can comprise using a laser to irradiate the surface of the substrate, forming a track of the laser direct structuring additive, and applying a conductive metal to the track. The laser direct structuring additive can comprise a metal oxide particle (such as titanium oxide and copper chromium oxide). The laser direct structuring additive can comprise a spinel-based inorganic metal oxide particle, such as spinel copper. The metal oxide particle can be coated, for example, with a composition comprising tin and antimony (for example, 50 to 99 wt% of tin and 1 to 50 wt% of antimony, based on the total weight of the coating). The laser direct structuring additive can comprise 2 to 20 parts of the additive based on 100 parts of the composition. The irradiating can be performed with a YAG laser having a wavelength of 1,064 nanometers under an output power of 10 Watts, a frequency of 80 kilohertz, and a rate of 3 meters per second. The conductive metal can be applied using a semi-additive plating process in an electroless and/or electrolytic plating bath comprising, for example, copper.

The electrically conductive layer can comprise at least one of stainless steel, copper, gold, silver, aluminum, zinc, tin, lead, nickel, or a transition metal such as palladium. There are no particular limitations regarding the thickness of the electrically conductive layer, nor are there any limitations as to the shape, size, or texture of the surface of the electrically conductive layer. The electrically conductive layer can have a thickness of 3 to 200 micrometers, or 9 to 180 micrometers. When two or more electrically conductive layers are present, the thickness of the two layers can be the same or different. The electrically conductive layer can comprise a copper layer. Suitable electrically conductive layers include a thin layer of an electrically conductive metal such as a copper foil presently used in the formation of circuits, for example, electrodeposited or annealed copper foils such as, but not limited to highly cubic oriented grain structure annealed copper foils exhibiting folding flexibility (high flex fatigue) such as HA, HA-V2 and HG commercially available from JX Nippon Mining & Metals of Tokyo, Japan.

The copper foil can have a root mean squared (RMS) roughness of less than or equal to 5 micrometers, or 0.1 to 3 micrometers, or 0.05 to 0.7 micrometers. As used herein, the roughness of the electrically conductive layer can be determined by atomic force microscopy in contact mode, reporting the Rz in micrometers calculated by determining the sum of five highest measured peaks minus the sum of the five lowest valleys and then dividing by five (JIS (Japanese Industrial Standard)-B-0601); or the roughness can be determined using white light scanning interferometry in contactless mode and is reported as Sa, Sq, Sz height parameters in micrometers using a stitching technique to characterize treated-side surface topography and texture (ISO 25178). The copper foil can be a battery foil layer having a zinc free low profile treated side roughness, for example, having at least one of an Sa of 0.05 to 0.4, an Sq of 0.01 to 1, an Sz of 0.5 to 10, or an Sdr of 0.5 to 30%.

An article can comprise the composite. The article can comprise a multilayer article that can comprise the composite layer and at least one additional layer. The composite layer can have a thickness of 5 to 200 micrometers, or 5 to 75 micrometers. The multilayer article can further comprise at least one of a copper layer, a glass layer, a liquid crystalline polymer (LCP) layer, an ultralow-CTE polyimide film layer, a fluoropolymer layer, a ceramic layer, a polyaramid layer, an epoxy layer, or a polyether layer.

The article can be a prepreg, a resin-coated electrically conductive (RCC) layer, a circuit board, a bond ply, a cover film, a build-up material, a build-up film, or a flexible core. The composite can be a non-clad or declad dielectric layer, a single clad dielectric layer, or a double clad dielectric layer. The article can be a semiconductor substrate build-up/redistribution layer dielectric film.

A double clad laminate has two electrically conductive layers, one on each side of the composite. A circuit material can comprise the composite. The circuit material is a type of circuit subassembly that has an electrically conductive layer, for example, copper, fixedly attached to a composite. Patterning the electrically conductive layer, for example by printing and etching, can provide the circuit. A multilayer circuit can comprise a plurality of electrically conductive layers, at least one of which contains an electrically conductive wiring pattern. Typically, multilayer circuits are formed by laminating two or more materials in proper alignment together, at least one of which contains a circuit layer, using bond plies, while applying heat or pressure. The circuit material can itself function as an antenna.

The bond ply can be unreinforced such that it is free of a reinforcing fabric. The bond ply can be an adhesive that is used, for example, in printed circuit materials. The bond ply can be used in bonding two neighboring layers. The bond ply can have good flow properties such that it can form layers having a thickness of less than 15 micrometers. The bond ply can be flexible and can used for flex or rigid flex applications.

The build-up material can be used for semiconductor applications such as, but not limited to, forming one or more redistribution layers (RDL). For example, the composite is particularly suited for advanced packaging substrates comprising a glass core such as an antenna-in-package (AiP), a system-in-package (SiP) and/or a system on an integrated chip (SoIC). Multiple integrated chips can be enclosed in one or more chip carrier packages as part of a package-on-package (PoP). Such packages integrate radio frequency (RF), analog, or digital functions and include active and passive system components in a single module. Applications for such devices include enhanced mobile broadband (eMBB), ultra-reliable and low latency communications (URLLC), massive machine type communications (mMTC) and high frequency, high speed machine-to-cloud communications. Substrates for such devices typically include low temperature co-fired ceramics (LTCC), multi-layered organics comprising prepreg and copper-clad laminates (such as FR4 epoxy), fan-out wafer level (FOWLP) epoxy molding compounds, or glass. The build-up material can therefore comprise a layer comprising the composite located on a stabilizing core layer comprising at least one of a glass, a polyimide film layer exhibiting an ultralow isotropic CTE comparable to silicon, a reinforced layer (for example, an aramid fiber reinforced polyimide or a glass fiber reinforced epoxy), a ceramic layer, an organic film layer containing a significant amount of ceramic filler or a non-reinforced epoxy layer.

The multilayer material, for example, the build-up material can comprise a glass substrate. Because glass substrates exhibit high elastic modulus, excellent dimensional stability, minimal warpage, and relatively lower cost, they are particularly suited to enable improved processing precision. Glass also exhibits an extremely smooth and a planar topography. The composition of the glass can also be formulated to achieve a coefficient of thermal expansion (CTE) comparable to silicon and also be photo-imageable, thereby enabling photo-definition of vias and strategically placed cavities within the overall design. A composite layer combined with a thin photo-definable glass substrate can enable an optimal combination of low dielectric loss, strategic incorporation of air as a dielectric material, strategic incorporation of cavities to house GPU, logic and/or memory chiplets and/or enable cooling, multi-layered wiring density comprising photo-defined vias in both the build-up redistribution composite layers as well as in the glass substrate, precision processing, amenable assembly, and subsequent reliability.

As disclosed herein, the thermosettable composition can comprise an imide extended compound of at least one of Formula 1 or Formula 2 and a reactive monomer that is free-radically crosslinkable with the reactive end groups of the imide extended compound to produce a crosslinked network. In Formula 1 or Formula 2, each R independently can be a divalent substituted or unsubstituted aliphatic, alkenyl, aromatic, or heteroaromatic group, or is a divalent siloxane group; each Q independently can be a divalent or tetravalent substituted or unsubstituted aliphatic, alkenyl, aromatic, or heteroaromatic group, or a divalent siloxane group, and each R₂ independently can comprise a reactive alkenyl end group. In Formula (1) or Formula 2, each R₂ independently can comprise a maleimide group, a citraconimide group, a styryl group, a vinylbenzyl group, a vinyl group, an allyl group, an alkynyl group, a propargyl ether group, a cyano group, a vinyl ether group, a vinyl ester group, an acrylate group, a methacrylate group, an oxazoline group, a benzoxazine group, or a methyl norbornene group. The imide extended compound can comprise a bis-maleimide compound of the Formula (3). The imide extended compound can comprise a bis-styryl compound of the Formula (4). The imide extended compound can comprise a bis-vinylbenzyl compound of the Formula (5). The imide extended compound can comprise a bis-vinyl compound of the Formula (6). The imide extended compound can comprise a bis-allyl compound of the Formula (7). The imide extended compound can comprise a compound having of the Formula (8). The degree of polymerization of the imide extended compound can be 1 to 100 or 2 to 10. The thermosettable composition can comprise 10 to 90 volume percent, or 25 to 75 volume percent, or 30 to 50 volume percent of the imide extended compound based on the total volume of the composition. The reactive monomer can comprise a triallyl (iso)cyanurate. The composition can comprise 1 to 40 volume percent, or 10 to 35 volume percent, or 20 to 30 volume percent of the reactive monomer based on the total volume of the composition.

The thermosettable composition can further comprise at least one of a free-radical initiator, a fused silica, a functionalized fused silica, a flame retardant, or a ceramic filler. The thermosettable composition can comprise the free-radical initiator. The free-radical initiator can comprise at least one of dicumyl peroxide, dimethyl diphenyl hexane, methyl ethyl ketone peroxide, cyclohexanone peroxide, 1,1-bis(t-butyl peroxy)-3,3,5-trimethylcyclohexane, 2,2-bis(t-butyl peroxy)butane), t-butyl hydroperoxide, 2,5-dimethylhexane-2,5-dihydroperoxide, t-butyl perbenzoate, α, α′-di-(t-butyl peroxy) diisopropylbenzene, or 2,5-dimethyl-2,5-di(t-butylperoxy)-3-hexyne, octanoyl peroxide, isobutyryl peroxide), peroxydicarbonate, α,α′-azobis(isobutyronitrile), a redox initiator, acetyl azide, 2,3-dimethyl-2,3-diphenylbutane, 3,4-dimethyl-3,4-diphenylhexane, or poly(1,4-diisopropylbenzene). The composition can comprise 0.1 to 10 volume percent, or 2 to 8 volume percent of the free-radical initiator based on the total volume of the composition. The thermosettable composition can comprise the fused silica. The fused silica can have a spherical morphology having a median diameter of 1 to 50 micrometers, or 1 to 10 micrometers. The thermosettable composition can comprise the functionalized fused silica that is capable of chemically coupling to the crosslinked network. The functionalized fused silica can have a spherical morphology having a median diameter of 1 to 50 micrometers, or 1 to 10 micrometers. The functional groups of the functionalized fused silica can comprise at least one of a (meth)acrylate group, a vinyl group, an allyl group, a propargyl group, a butenyl group, styryl group, or a vinyl benzyl. The functional group of the functionalized fused silica can comprise a (meth)acrylate group. The thermosettable composition can comprise 10 to 70 volume percent, or 20 to 60 volume percent, or 30 to 55 volume percent of the fused silica and/or the functionalized fused silica based on the total volume of the composition. The thermosettable composition can comprise the flame retardant. The flame retardant can be present in an amount of 5 to 25 volume percent, or 8 to 20 volume percent of a flame retardant based on the total volume of the composition. The thermosettable composition can comprise the ceramic filler. The ceramic filler can comprise at least one of fumed silica, titanium dioxide, barium titanate, strontium titanate, corundum, wollastonite, Ba₂Ti₉O₂₀, hollow ceramic spheres, boron nitride, aluminum nitride, silicon carbide, beryllia, alumina, alumina trihydrate, magnesia, mica, talc, nanoclay, or magnesium hydroxide.

The thermosettable composition can comprise 10 to 90 volume percent volume percent of the imide extended bismaleimide of the Formula (8); 1 to 40 volume percent of a triallyl (iso)cyanurate; 0.1 to 10 volume percent of the free-radical initiator; and 10 to 70 volume percent of a methacrylate functionalized fused silica; wherein the volumes are based on the total volume of the thermosettable composition.

A thermoset composite can be from the thermosettable composition. The composite can have a peel strength to copper of greater than or equal to 0.35 kilograms per centimeter. The composite can have an average coefficient of thermal expansion in the z-direction of less than or equal to 40 parts per million per degree Celsius, or less than or equal to 35 parts per million per degree Celsius from -50 to 150° C. The composite can have a permittivity of 2.5 to 3.5 at 10 gigahertz. The composite can have a dielectric loss of less than or equal to 0.0025, or less than or equal to 0.0020, or 0.001 to 0.0025 at 10 gigahertz. The composite can comprise a reinforcing woven or nonwoven fabric. The reinforcing fabric can comprise at least one of NE glass fibers, L glass fibers, or quartz fibers. The reinforcing fabric can comprise at least one of liquid crystalline polymer (LCP) fibers, aramid fibers, cyclic-olefin-copolymer (COC) fibers or ultrahigh molecular weight polyethylene (UHMWPE) fibers. The reinforcing fabric can be a spread-weave reinforcing fabric. The reinforcing fabric can be present in an amount of 5 to 40 weight percent, or 15 to 25 weight percent based on the total weight of the thermoset composite.

A method of making the composite can comprise curing a layer formed from the composition. The curing can comprise at least one increasing a temperature of the layer or exposing the layer to an electron-beam irradiation or exposing the layer to ultraviolet (UV) irradiation. The method can comprise forming the layer by casting the composition on a release liner. The method can comprise forming the layer by casting the composition on a metal foil such as copper or aluminum. The method can comprise impregnating a reinforcing layer with the composition prior to the curing.

An article can comprise the composite. The article can be a multilayer article. The multilayer article can comprise at least one of a copper layer, a glass layer, a liquid crystalline polymer (LCP) layer, an ultralow-CTE polyimide film layer, a fluoropolymer layer, a ceramic layer, a polyaramid layer, an epoxy layer, or a polyether layer. The article can be an antenna, a bond ply, a build-up film, a circuit board, resin-coated-copper (RCC), or a flexible core.

The following examples are provided to illustrate the present disclosure. The examples are merely illustrative and are not intended to limit devices made in accordance with the disclosure to the materials, conditions, or process parameters set forth therein.

### EXAMPLES

In the examples, the permittivity (Dk) and the dielectric loss (Df) (also referred to as the loss tangent) were measured in accordance with the “Split Post Dielectric Resonator (SPDR) Technique for Precise Measurements of Laminar Dielectric Specimens” (IEEE Xplore Conference Paper, February 2000) at a temperature of 23 to 25° C., 50% relative humidity and at a frequency of 10 gigahertz (GHz).

The wet and the dry film ratings were arbitrarily and relatively assigned, where 0 is the worst rating and 3 is the best rating.

The coefficients of thermal expansion (CTE) in the z-direction were determined in accordance with the “Glass Transition Temperature and Thermal Expansion of Materials Used in High Density Interconnection (HDI) and Microvias - TMA Method” (IPC-TM-650 2.4.24.5). The units are reported in parts per million per degree Celsius (ppm/°C).

Elastic modulus was determined in accordance with “Glass Transition and Modulus of Materials Used in High Density Interconnection (HDI) and Microvias - DMA Method” (IPC-TM-650 2.4.24.4). The units are reported in giga pascals (GPa).

Peel strength was determined in accordance with “Peel Strength of Metallic Clad Laminates” (IPC-TM-650 2.4.8). The units are reported in pounds per inch (lbs/in).

The flame rating was determined in accordance with the Underwriter’s Laboratory UL 94 Standard For Safety “Tests for Flammability of Plastic Materials for Parts in Devices and Appliances,” where a flame rating of V0 is the most difficult to achieve, requiring that five test specimens of the test material self-extinguish with an average flame out time of five seconds or less without dripping. The tests were performed on 6 mil (0.15 millimeter) thick samples.

The ash content was determined using a high temperature furnace to fully decompose and oxidize all organic substances within the test sample and determining the amount of residual inorganic substances by weight.

The minimum melt viscosity (MMV) was determined using parallel plate oscillatory rheology with a ramping temperature of 10° C. per minute. The viscosity and temperature where the film starts to soften as it goes into a minimum melt and before the cross-linker begins to pick up molecular weight is taken as the minimum melt viscosity and corresponding temperature.

In the examples, the terminology of a 1 ounce copper foil refers to the thickness of the copper layer achieved when 1 ounce (29.6 milliliters) of copper is pressed flat and spread evenly over a one square foot (929 centimeters squared) area. The equivalent thickness is 1.37 mils (0.0347 millimeters). A ½ ounce copper foil correspondingly has a thickness of 0.01735 millimeters.

The components used in the examples are shown in Table 1.

TABLE 1

| | | |
|---|---|---|
| m-Fused silica | Spherical fused silica, grade FB-8S, median diameter of 8 micrometers from Denka, methacrylated at Rogers | Modified Denko |
| Imide extended compound-1 | SFR-2300MR-T; a difunctional imide-extended-bismaleimide having a high aliphatic character | Showa Denko |
| Imide extended compound-2 | BMI 5000 a difunctional imide-extended-bismaleimide having a high aliphatic character | Designer Molecules |
| TAIC | Triallyl isocyanurate | Evonik |
| Initiator-1 | DYBP, 2,5-dimethyl-2,5-di(t-butylperoxy)-3-hexyne | Evonik |
| FR-1 | Flame retardant, EXOLIT OP 1311 | Clariant |
| PPO-high Mw | NORYL™ PPE 640, poly(phenylene ether) having a weight average molecular weight of 56,200 g/mol | SABIC |
| PPO-low Mw | NORYL™ PPE SA120, poly(phenylene ether) having a weight average molecular weight of 6,300 g/mol | SABIC |
| Compatibilizer | RICON™ 184 MA6, maleic anhydride functionalized butadiene-styrene block copolymer having a number average molecular weight of 9,100 g/mol containing 17 to 27 w/w % styrene monomer as a reactive diluent. | Cray Valley |
| SB-diblock | KRATON™ D1118, styrene-butadiene diblock copolymer | Kraton Corporation |
| TNG | SC-2050-TNG, a ~70 w/w % dispersion of amorphous silica (0.2 to 2.0 µm) in toluene contains 3-methacryloxypropyltrimethoxysilane. | Adamatechs |
| Heat stabilizer | CHIMASSORB™ 944LD, a high molecular weight oligomeric hindered amine light stabilizer (HALS) and heat stabilizer. | BASF |
| Initiator-2 | PERKADOX IPP-NA30, organic peroxide initiator | Nouryon |
| Cu foil-1 | Rolled Annealed (RLD) | Wieland |
| Cu foil-2 | SQ-VLP | Oak Mitsui__ |
| Cu foil-3 | MLS | Oak Mitsui |

### Example 1: Preparation of an Imide Extended Composite

A thermosetting imide extended composition comprising 55 wt% of solids as described in Table 2 in toluene was formed.

TABLE 2

| Material | vol% |
|---|---|
| m-fused silica | 35.0 |
| Imide extended compound-1 | 22.4 |
| TAIC | 21.0 |
| FR-1 | 19.4 |
| Initiator-1 | 2.2 |

The thermosetting composition was cast using a knife over roll technique on a 2 mil (50.8 micrometer) poly(ethylene terephthalate) substrate. The casting was performed at a line speed of 9 ft/min (2.7 meters/minute) through four heating zones at increasing temperatures of 180° F. (82° C.), 220° F. (104° C.), 220° F. (104° C.), and 300° F. (149° C.). The cast composite was then laminated at a temperature of 360° F. (182° C.) for 2 hours at a pressure of 0.7 pounds per square inch (4.8 kilopascal).

### Example 2: Preparation of a Poly(phenylene Oxide) (PPO) Composite

A thermosetting composition containing PPO was formed as described in Table 3.

TABLE 3

| Material | vol% |
|---|---|
| PPO-high Mw | 14.3 |
| TAIC | 12.4 |
| Compatibilizer | 14.8 |
| PPO-low Mw | 4.5 |
| SB diblock | 14.8 |
| TNG | 34.2 |
| Heat stabilizer | 0.8 |
| Initiator-2 | 4.2 |

The thermosetting composition was cast using a knife over roll technique on a 2 mil poly(ethylene terephthalate) substrate. The casting was performed at a line speed of 10 ft/min (3 meters/minute) through four heating zones at increasing temperatures of 150° F. (66° C.), 200° F. (93° C.), 220° F. (104° C.), and 220° F. (104° C.). The cast composite was then laminated at a temperature of 450° F. (232° C.) for 2 hours at a pressure of 0.7 pounds per square inch (4.8 kilopascal).

### Example 3: Comparison of the Imide Extended Composite and the PPO Composite

Various properties of the composites of Examples 1 and 2 were measured and are provided in Table 4.

TABLE 4

| | | |
|---|---|---|
| Example | 1 | 2 |
| Wet Film Rating | 2 | 3 |
| Dry Film Rating | 3 | 3 |
| Dk | 2.93 | 2.94 |
| Df | 0.0022 | 0.003 |
| CTE-z (150 to 250° C.) (ppm/°C) | 27 | - |
| CTE-z (-50 to 150° C.) (ppm/°C) | 30 | 50 |
| CTE-z (-50 to 250° C.) (ppm/°C) | 23 | - |
| Flame Rating | V0 | HB |
| Elastic Modulus (GPa) | 0.65 | 5.65 |
| Ash Content (%) | 67.0 | - |

Table 4 shows that the imide extended composite has a reduced dielectric loss, a reduced z-direction coefficient of thermal expansion, lower elastic modulus, and an improved flame rating relative to the PPO composite of Example 2.

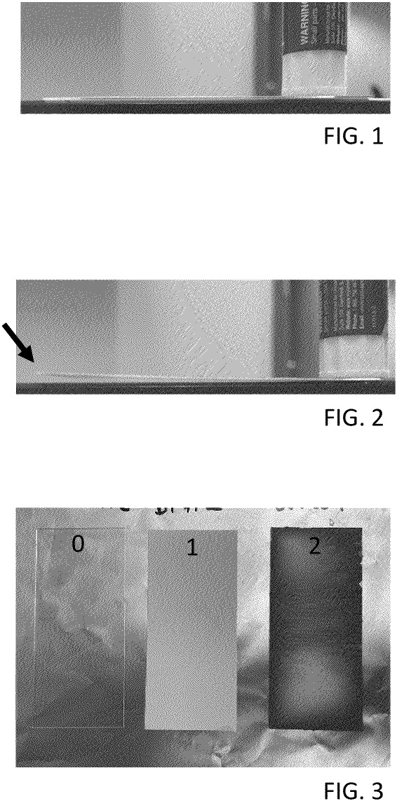

Moreover, the PPO composite was observed to warp, i.e., it did not remain flat after curing, stress cracked, and was found to be more thermally oxidative relative to the imide extended composite of Example 1, which remained flat without observable stress cracking. These results can be observed in FIG. 1, FIG. 2, and FIG. 3. FIG. 1 is a photographic image of a imide extended composite of Example 1 lying flat on a table. FIG. 2 is a photographic image of a PPO composite of Example 2 that is bent as is indicated by arrow pointing to the higher corner. FIG. 3 is a photographic image of three glass substrates where substrate 0 is uncoated for reference, substrate 1 was laminated with the imide extended composite of Example 1, and substrate 2 was laminated with the PPO of Example 2. Substrate 1 is free of stress cracking, whereas Substrate 2 exhibits significant stress cracking.

### Examples 4-5: Effect of the Methacrylate Fused Silica Percent Volume Loading on the Imide Extended Composite

Two imide extended composites were prepared in accordance with Example 1 using the thermosetting compositions as shown in Table 5 and where the thermosetting compositions were laminated on as-received glass substrates and on the shiny-side of rolled annealed copper (½ ounce RLD, hyper-very-low-profile) that had been treated with 1% aqueous sulfuric acid prepared by taking 1.05 grams of concentrated sulfuric acid (95-98%) and diluting it to 100 mL. Various properties were measured and are shown in Table 5.

TABLE 5

| Example | 4 | 5 |
|---|---|---|
| m-fused silica | 40.0 | 35.0 |
| Imide extended compound-1 | 28.2 | 30.5 |
| TAIC | 26.3 | 28.5 |
| Initiator-1 | 5.5 | 6.0 |
| Properties | | |
| Minimum melt viscosity (Poise) | 2,521 | 2,123 |
| Dk at 10 GHz | 0.0016 | 0.0019 |
| Df at 10 GHz | 3.1 | 3.6 |
| CTE-z (150 to 250° C.) (ppm/°C) | 62 | 83 |
| CTE-z (-50 to 150° C.) (ppm/°C) | 73 | 93 |
| CTE-z (-50 to 250° C.) (ppm/°C) | 59 | 77 |
| Cu foil-1 peel strength (shiny-side) | 1.8 - 2.0 | 1.8 - 2.0 |

These results illustrate the effect of the higher methacrylate fused silica percent volume loading on reducing the resultant coefficient of thermal expansion.

### Examples 6-10: Effect of the Imide Extended Compound on the CTE-z of the Resulting Imide Extended Composites

Five composites were prepared using different difunctional imide extended compounds as shown in Table 6. The resulting properties were determined and are also shown in Table 6.

TABLE 6

| Example | 6 | 7 | 8 | 9 | 10 |
|---|---|---|---|---|---|
| Imide extended compound-1 (vol%) | 25.3 | 22.4 | - | - | - |
| Imide extended compound-2 (vol%) | - | - | 24.1 | 21.4 | 18.7 |
| TAIC (vol%) | 23.5 | 20.9 | 24.3 | 21.6 | 18.9 |
| m-fused silica (vol%) | 30.0 | 35.0 | 30.0 | 35.0 | 40.0 |
| FR-1 (vol%) | 18.7 | 19.4 | 19.0 | 19.7 | 20.4 |
| Initiator-1 (vol%) | 2.5 | 2.3 | 2.6 | 2.3 | 2.0 |
| Properties | | | | | |
| Df at 10 GHz | 0.0020 | 0.0026 | 0.0028 | 0.0028 | 0.0029 |
| Dk at 10 GHz | 2.59 | 3.29 | 3.32 | 3.31 | 3.11 |
| MMV (Poise) | 205.7 | 184.2 | 159.0 | 265.0 | 242.0 |
| CTE-z (-50 to 150° C.) (ppm/°C) | 29 | 28 | 106 | 76 | 206 |
| CTE-z (150 to 250° C.) (ppm/°C) | 45 | 52 | 220 | 169 | 506 |
| CTE-z (-50 to 250° C.) (ppm/°C) | 30 | 31 | 144 | 101 | 310 |
| Cu foil-2 peel strength (pli) | 4.0 | 2.0 | 4.5 | 2.0 | 0.6 |
| Cu foil-3 peel strength (pli) | 2.6 | 2.0 | 3.2 | 2.8 | 1.5 |
| Flame rating | V0 | V0 | V0 | V0 | V0 |
| Elastic modulus (GPa) | 0.9 | 1.4 | 0.9 | 1.4 | 1.1 |

Table 6 shows that the CTE-z values were greater for thermally cured composites containing imide extended compound-2 relative to those containing the imide extended compound-1. These results illustrate the effect of the imide extended compound on the resultant coefficient of thermal expansion.

Set forth below are various non-limiting aspects of this disclosure.

Aspect 1: A thermosettable composition comprising: an imide extended compound of the following structure:

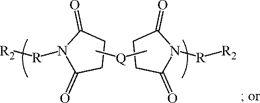

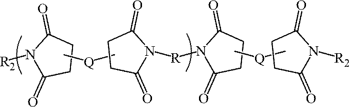

wherein R and Q are each independently divalent substituted or unsubstituted aliphatic, alkenyl, aromatic, heteroaromatic groups, or a divalent siloxane group; and each R₂ independently comprises a reactive alkenyl end group; and a reactive monomer that is free-radically crosslinkable with the reactive end groups of the imide extended compound to produce a crosslinked network.

Aspect 2: The thermosettable composition of Aspect 1, each R₂ independently comprises a maleimide group, a citraconimide group, a styryl group, a vinylbenzyl group, a vinyl group, an allyl group, an alkynyl group, a propargyl ether group, a cyano group, a vinyl ether group, a vinyl ester group, an acrylate group, a methacrylate group, an oxazoline group, a benzoxazine group, or a methyl norbornene group.

Aspect 3: The thermosettable composition of any of the preceding aspects, wherein the imide extended compound comprises a bis-maleimide compound of the following formula:

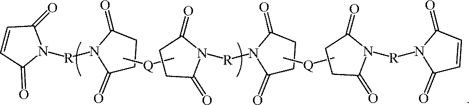

Aspect 4: The thermosettable composition of any of the preceding aspects, wherein the imide extended compound comprises a bis-styryl compound of the following formula:

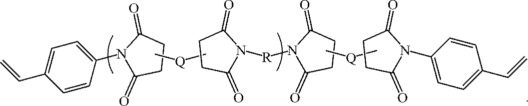

Aspect 5: The thermosettable composition of any of the preceding aspects, wherein the imide extended compound comprises a bis-vinylbenzyl compound of the following formula:

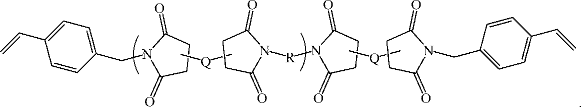

Aspect 6: The thermosettable composition of any of the preceding aspects, wherein the imide extended compound comprises a bis-vinyl compound of the following formula:

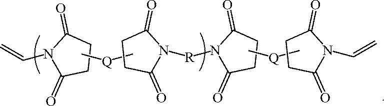

Aspect 7: The thermosettable composition of any of the preceding aspects, wherein the imide extended compound comprises a bis-allyl compound of the following formula:

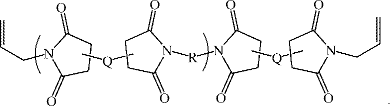

Aspect 8: The thermosettable composition of any one of the preceding aspects, wherein the imide extended compound comprises a compound having the formula:

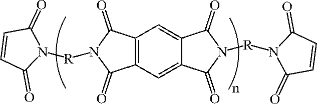

wherein n is an integer 1 to 100, or 2 to 10.

Aspect 9: The thermosettable composition of any one or more of the preceding aspects, wherein the composition comprises 10 to 90 volume percent, or 25 to 75 volume percent, or 30 to 50 volume percent of the imide extended compound based on the total volume of the composition.

Aspect 10: The thermosettable composition of any one or more of the preceding aspects, wherein the reactive monomer comprises a triallyl (iso)cyanurate.

Aspect 11: The thermosettable composition of any one or more of the preceding aspects, wherein the composition comprises 1 to 40 volume percent, or 10 to 35 volume percent, or 20 to 30 volume percent of the reactive monomer based on the total volume of the composition.

Aspect 12: The thermosettable composition of any one or more of the preceding aspects, further comprising a free-radical initiator; wherein the free-radical initiator optionally comprises at least one of dicumyl peroxide, dimethyl diphenyl hexane, methyl ethyl ketone peroxide, cyclohexanone peroxide, 1,1-bis(t-butyl peroxy)-3,3,5-trimethylcyclohexane, 2,2-bis(t-butyl peroxy)butane), t-butyl hydroperoxide, 2,5-dimethylhexane-2,5-dihydroperoxide, t-butyl perbenzoate, α, α′-di-(t-butyl peroxy) diisopropylbenzene, or 2,5-dimethyl-2,5-di(t-butylperoxy)-3-hexyne, octanoyl peroxide, isobutyryl peroxide), peroxydicarbonate, α,α′-azobis(isobutyronitrile), a redox initiator, acetyl azide, 2,3-dimethyl-2,3-diphenylbutane, 3,4-dimethyl-3,4-diphenylhexane, or poly(1,4-diisopropylbenzene) and/or wherein the composition comprises 0.1 to 10 volume percent, or 2 to 8 volume percent of the free-radical initiator based on the total volume of the composition.

Aspect 13: The thermosettable composition of any one or more of the preceding aspects, further comprising a fused silica; wherein the fused silica optionally has a spherical morphology having a median diameter of 1 to 50 micrometers, or 1 to 10 micrometers.

Aspect 14: The thermosettable composition of any one or more of the preceding aspects, further comprising a functionalized fused silica that is capable of chemically coupling to the crosslinked network; wherein the functionalized fused silica optionally has a spherical morphology having a median diameter of 1 to 50 micrometers, or 1 to 10 micrometers.

Aspect 15: The thermosettable composition of any one or more of the preceding aspects, wherein the composition comprises 10 to 70 volume percent, or 20 to 60 volume percent, or 30 to 55 volume percent of the fused silica based on the total volume of the composition.

Aspect 16: The thermosettable composition of any one or more of the preceding aspects, wherein the composition comprises 10 to 70 volume percent, or 20 to 60 volume percent, or 30 to 55 volume percent of the functionalized fused silica based on the total volume of the composition.

Aspect 17: The thermosettable composition of any one or more of the preceding aspects, wherein the fused silica is functionalized with functional groups comprising at least one of a (meth)acrylate group, a vinyl group, an allyl group, a propargyl group, a butenyl group, styryl group, or a vinyl benzyl; preferably wherein a functional group of the functionalized fused silica comprises a (meth)acrylate group.

Aspect 18: The thermosettable composition of any one or more of the preceding aspects, further comprising 5 to 25 volume percent, or 8 to 20 volume percent of a flame retardant based on the total volume of the composition.

Aspect 19: The thermosettable composition of any one or more of the preceding aspects, further comprising a ceramic filler; wherein the ceramic filler optionally comprises at least one of fumed silica, titanium dioxide, barium titanate, strontium titanate, corundum, wollastonite, Ba₂Ti₉O₂₀, hollow ceramic spheres, boron nitride, aluminum nitride, silicon carbide, beryllia, alumina, alumina trihydrate, magnesia, mica, talc, nanoclay, or magnesium hydroxide.

Aspect 20: The thermosettable composition of any one or more of the preceding aspects, comprising 10 to 90 volume percent volume percent of the imide extended bismaleimide; wherein the compound has the formula:

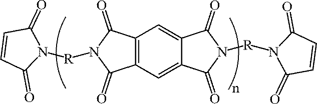

1 to 40 volume percent of a triallyl (iso)cyanurate; 0.1 to 10 volume percent of the free-radical initiator; and 10 to 70 volume percent of a methacrylate functionalized fused silica; wherein the volumes are based on the total volume of the thermosettable composition.

Aspect 21: A thermoset composite derived from the thermosettable composition of any one or more of the preceding aspects.

Aspect 22: The thermoset composite of Aspect 21, wherein the composite has at least one of a peel strength to copper of greater than or equal to 0.35 kilograms per centimeter; an average coefficient of thermal expansion in the z-direction of less than or equal to 40 parts per million per degree Celsius, or less than or equal to 35 parts per million per degree Celsius from -50 to 150° C.; a permittivity of 2.5 to 3.5 at 10 gigahertz; or a dielectric loss of less than or equal to 0.0025, or less than or equal to 0.0020, or 0.001 to 0.0025 at 10 gigahertz.

Aspect 23: The thermoset composite of any one of Aspects 21 to 22, further comprising a reinforcing fabric; wherein the reinforcing fabric optionally comprises at least one of NE glass fibers, L glass fibers, or quartz fibers, wherein the reinforcing fabric is optionally a spread-weave reinforcing fabric that is present in an amount of 5 to 40 weight percent, or 15 to 25 weight percent based on the total weight of the thermoset composite.

Aspect 24: The thermoset composite of any one of Aspects 21 to 22, further comprising a reinforcing woven or nonwoven fabric; wherein the reinforcing fabric optionally comprises at least one of liquid crystalline polymer (LCP) fibers, aramid fibers, cyclic-olefin-copolymer (COC) fibers or ultrahigh molecular weight polyethylene (UHMWPE) fibers wherein the reinforcing fabric is present in an amount of 5 to 40 weight percent, or 15 to 25 weight percent based on the total weight of the thermoset composite.

Aspect 25: A method of making the composite of any of Aspects 21 to 24 comprising: curing a layer formed from the composition of any one or more of Aspects 1 to 19.

Aspect 26: The method of Aspect 25, wherein the curing comprises at least one increasing a temperature of the layer or exposing the layer to an electron-beam irradiation or exposing the layer to ultraviolet (UV) irradiation.

Aspect 27: The method of any one or more of Aspects 25 to 26, further comprising forming the layer by casting the composition on a release liner.

Aspect 28: The method of any one or more of Aspects 25 to 27, further comprising forming the layer by casting the composition on a metal foil such as copper or aluminum.

Aspect 29: The method of any one or more of Aspects 25 to 28, further comprising impregnating a reinforcing layer with the composition prior to the curing.

Aspect 30: A multilayer article comprising the composite of any one or more of Aspects 21 to 24.

Aspect 31: The multilayer article of Aspect 30, further comprising at least one of a copper layer, a glass layer, a liquid crystalline polymer (LCP) layer, an ultralow-CTE polyimide film layer, a fluoropolymer layer, a ceramic layer, a polyaramid layer, an epoxy layer, or a polyether layer.

Aspect 32: An article comprising the composite of any one or more of Aspects 21 to 24.

Aspect 33: The article of Aspect 32, wherein the article is an antenna, a bond ply, a semiconductor substrate build-up/redistribution layer dielectric film, a circuit board, resin-coated-copper (RCC), or a flexible core.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise. The term “combination” is inclusive of blends, mixtures, alloys, reaction products, and the like. Also, “at least one of” means that the list is inclusive of each element individually, as well as combinations of two or more elements of the list, and combinations of at least one element of the list with like elements not named.

The term “or” means “and/or” unless clearly indicated otherwise by context.. Reference throughout the specification to “an aspect”, “another aspect”, “some aspects”, and so forth, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

It is noted that the amounts of the components of the thermosettable composition minus any solvent can correspond directly their respective amount in the resultant composite. For example, a composite derived from a thermosettable composition that comprises 25 vol% of fused silica, will itself comprises 25 vol% of fused silica based on the total volume of the composite. It is also noted that the amounts as indicated herein are based on the total weight or total volume of the composition or composite minus any solvent or reinforcing fabric.

The endpoints of all ranges directed to the same component or property are inclusive of the endpoints, are independently combinable, and include all intermediate points and ranges. For example, ranges of “up to 25 vol%, or 5 to 20 vol %” is inclusive of the endpoints and all intermediate values of the ranges of “5 to 25 vol %,” such as 10 to 23 vol %, etc.

Unless defined otherwise, technical and scientific terms used herein have the same meaning as is commonly understood by one of skill in the art to which this disclosure belongs.

Compounds are described using standard nomenclature. For example, any position not substituted by any indicated group is understood to have its valency filled by a bond as indicated, or a hydrogen atom. A dash (“-”) that is not between two letters or symbols is used to indicate a point of attachment for a substituent. For example, —CHO is attached through carbon of the carbonyl group. As used herein, the term “(meth)acryl” encompasses both acryl and methacryl groups.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

What is claimed is:

1. A thermosettable composition comprising:
an imide extended compound of the following structure: 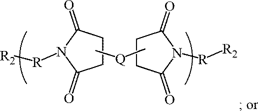 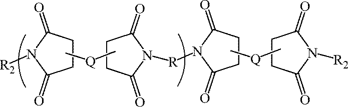
wherein R and Q are each independently divalent substituted or unsubstituted aliphatic, alkenyl, aromatic, heteroaromatic groups, or a divalent siloxane group; and each R₂ independently comprises a reactive alkenyl end group; and
a reactive monomer that is free-radically crosslinkable with the reactive end groups of the imide extended compound to produce a crosslinked network.

2. The thermosettable composition of claim 1, each R₂ independently comprises a maleimide group, a citraconimide group, a styryl group, a vinylbenzyl group, a vinyl group, an allyl group, an alkynyl group, a propargyl ether group, a cyano group, a vinyl ether group, a vinyl ester group, an acrylate group, a methacrylate group, an oxazoline group, a benzoxazine group, or a methyl norbornene group.

3. The thermosettable composition of claim 1, wherein the imide extended compound comprises a bis-maleimide compound of the following formula: 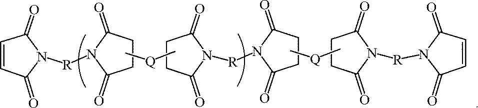
.

4. The thermosettable composition of claim 1, wherein the imide extended compound comprises a bis-styryl compound of the following formula: 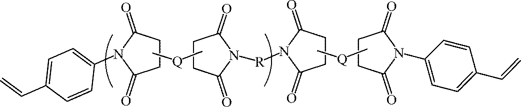
.

5. The thermosettable composition of claim 1, wherein the imide extended compound comprises a bis-vinylbenzyl compound of the following formula: 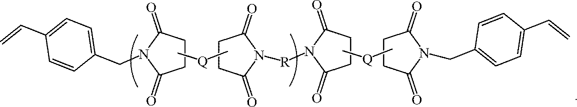
.

6. The thermosettable composition of claim 1, wherein the imide extended compound comprises a bis-vinyl compound of the following formula: 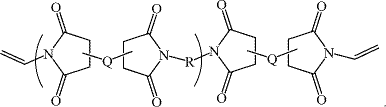
.

7. The thermosettable composition of claim 1, wherein the imide extended compound comprises a bis-allyl compound of the following formula: 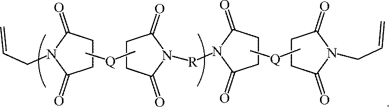
.

8. The thermosettable composition of claim 1, wherein the imide extended compound comprises a compound having the formula: 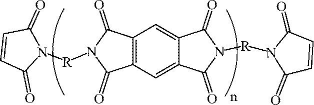
wherein n is an integer 1 to 100, or 2 to 10.

9. The thermosettable composition of claim 1, wherein the composition comprises 10 to 90 volume percent of the imide extended compound based on the total volume of the composition.

10. The thermosettable composition of claim 1, wherein the reactive monomer comprises a triallyl (iso)cyanurate.

11. The thermosettable composition of claim 1, wherein the composition comprises 1 to 40 volume percent of the reactive monomer based on the total volume of the composition.

12. The thermosettable composition of claim 1, further comprising
a fused silica, wherein the fused silica optionally has a spherical morphology having a median diameter of 1 to 50 micrometers, or
a functionalized fused silica that is capable of chemically coupling to the crosslinked network; wherein the functionalized fused silica optionally has a spherical morphology having a median diameter of 1 to 50 micrometers.

13. The thermosettable composition of claim 12, wherein the composition comprises 10 to 70 volume percent of the fused silica or the functionalized fused silica based on the total volume of the composition.

14. The thermosettable composition of claim 1, further comprising 5 to 25 volume percent, or 8 to 20 volume percent of a flame retardant based on the total volume of the composition.

15. The thermosettable composition of claim 1, further comprising a ceramic filler; wherein the ceramic filler optionally comprises at least one of fumed silica, titanium dioxide, barium titanate, strontium titanate, corundum, wollastonite, Ba₂Ti₉O₂₀, hollow ceramic spheres, boron nitride, aluminum nitride, silicon carbide, beryllia, alumina, alumina trihydrate, magnesia, mica, talc, nanoclay, or magnesium hydroxide.

16. The thermosettable composition of claim 1, comprising:
10 to 90 volume percent volume percent of the imide extended bismaleimide; wherein the compound has the formula: 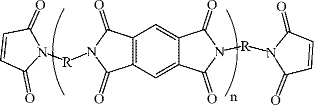
1 to 40 volume percent of a triallyl (iso)cyanurate;
0.1 to 10 volume percent of the free-radical initiator; and
10 to 70 volume percent of a methacrylate functionalized fused silica;
wherein the volumes are based on the total volume of the thermosettable composition.

17. A thermoset composite derived from the thermosettable composition of claim 1.

18. A method of making the composite of claim 17 comprising:
curing a layer formed from the composition of claim 1.

19. A multilayer article comprising the composite of claim 17.

20. An article comprising the composite of claim 17.
